(19) United States
(12) Patent Application Publication
(10) Pub. No.: US 2025/0308586 A1
(43) Pub. Date: Oct. 2, 2025

(54) METHODS AND APPARATUS FOR EFFICIENT CONTENT ADDRESSABLE MEMORY AND SEARCH ENGINE HARDWARE

(71) Applicant: Khalifa University of Science And Technology, Abu Dhabi (AE)

(72) Inventor: Baker Mohammad, Abu Dhabi (AE)

(21) Appl. No.: 19/088,054

(22) Filed: Mar. 24, 2025

Related U.S. Application Data
(60) Provisional application No. 63/571,239, filed on Mar. 28, 2024.

(51) Int. Cl. G11C 11/419; G11C 11/418; G11C 15/04

(52) U.S. Cl. CPC G11C 11/419; G11C 11/418; G11C 15/04

(57) ABSTRACT

A content-addressable memory (CAM) search architecture can involve separating two data string types for a system. The system can include a CAM array. The CAM array can include n rows and m columns of CAM elements. Each column of the m columns can include a set with n CAM elements. The CAM array can also include a first word line and a second word line in each row of the n rows. Additionally, the CAM array can include a first bit line and a second bit line in each column of the m columns. The system can also include a write data driver. The write data driver can simultaneously write data to multiple static random-access memory (SRAM) cells of a CAM element in each set in the CAM array in multiple write steps.

### CROSS-REFERENCES TO RELATED APPLICATIONS

This application claims the benefit of U.S. Provisional Patent Application No. 63/571,239, filed Mar. 28, 2024, the entire contents of which are hereby incorporated by reference for all purposes in its entirety.

### BACKGROUND OF THE INVENTION

Implementation of a hardware-based searches can be challenging due to a high cost on power and area. Adaption of hardware-based searches can be limited to prioritized applications such as lookup in memory (e.g., tag array, translation lookaside buffer, routers). With a new computing paradigm associated with an increase in use of artificial intelligence (AI) and big data, a more efficient lookup to implement functions (e.g., binary convolutional neural networks (CNN), a similarity index, etc.) using hardware can be beneficial. A hardware implementation of lookup and search can use less power and lead to faster lookup when compared to a software approach.

### BRIEF SUMMARY OF THE INVENTION

A content-addressable memory (CAM) search architecture can involve separating two data string types for a CAM memory cell. For example, a system described herein can include a CAM array. The CAM array can include n rows and m columns of CAM elements. Each column of the m columns can include a set with n CAM elements. The CAM array can also include a first word line and a second word line in each row of the n rows. Additionally, the CAM array can include a first bit line and a second bit line in each column of the m columns. The system can also include a write data driver. The write data driver can simultaneously write data to multiple static random-access memory (SRAM) cells of a CAM element in each set in the CAM array in multiple write steps.

In another example, a method described herein can include writing, simultaneously, data in multiple write steps to multiple static random access memory (SRAM) cells of each content-addressable memory (CAM) element in each set of a CAM array. The CAM array can include n rows and m columns of CAM elements. Each column of the m columns can include a set with n CAM elements. The CAM array can also include a first word line and a second word line in each row of the n rows. Additionally, the CAM array can include a first bit line and second bit line in each column of the m columns.

### BRIEF DESCRIPTION OF THE DRAWINGS

FIG. 1 is a schematic of a ten-transistor CAM cell.

FIG. 2 is a top-level view of an example of CAM-based architecture.

FIG. 3 is a schematic of a full CAM cell with a table of a complimentary bit line code associated with the full CAM cell according to certain aspects of the present disclosure.

FIG. 4 is a schematic of a key and slot configuration for a compare operation of CAM architecture according to certain aspects of the present disclosure.

FIG. 5 is a schematic of a CAM-based system for implementing a CAM search architecture according to certain aspects of the present disclosure.

FIG. 6 is a schematic of an SRAM cell for implementing a CAM search architecture according to certain aspects of the present disclosure.

FIG. 7 is a diagram indicating signals of components in a CAM-based array during various operations according to certain aspects of the present disclosure.

FIG. 8 is a flow chart of a process for implementing operations associated with a CAM search architecture according to certain aspects of the present disclosure.

FIG. 9 is a block diagram of a computing device that includes a CAM-based system according to certain aspects of the present disclosure.

FIG. 10 is a schematic of an analyzed CAM-based system for implementing a CAM search architecture according to certain aspects of the present disclosure.

FIG. 11 is a graph with plots of timing waveforms associated with an SRAM array of a CAM-based system for implementing a CAM search architecture according to certain aspects of the present disclosure.

FIG. 12 is a graph with plots of timing waveforms associated with an CAM array of a CAM-based system for implementing a CAM search architecture according to certain aspects of the present disclosure.

FIG. 13 is a graph with plots of timing waveforms associated with a similarity index array of a CAM-based system for implementing a CAM search architecture according to certain aspects of the present disclosure.

FIG. 14 is a graph with plots of voltage dependences on a number of identified mismatches for a first bit line and a second bit line in a CAM array of a CAM-based system according to certain aspects of the present disclosure.

### DETAILED DESCRIPTION OF THE INVENTION

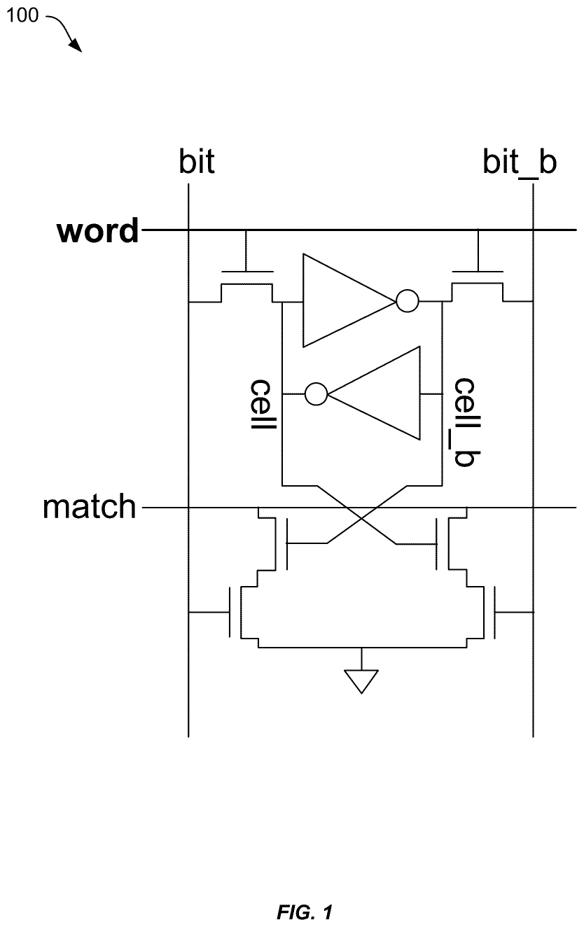

FIG. 1 is a schematic of a ten-transistor content-addressable memory (CAM) cell. CAM based circuits can allow input data to be rapidly searched for any match within a memory. CAM memory can be a storage structure that accesses memory by content rather than by location. In addition to write and read operations that can be supported by static random-access memory (SRAM) and dynamic RAM (DRAM), CAM can allow massively parallel search operations between an input query pattern and an entire dataset stored within a memory content. The ten-transistor CAM cell can include a word line, a match line, and associated bit lines, which can also be referred to as search lines in CAM based memory.

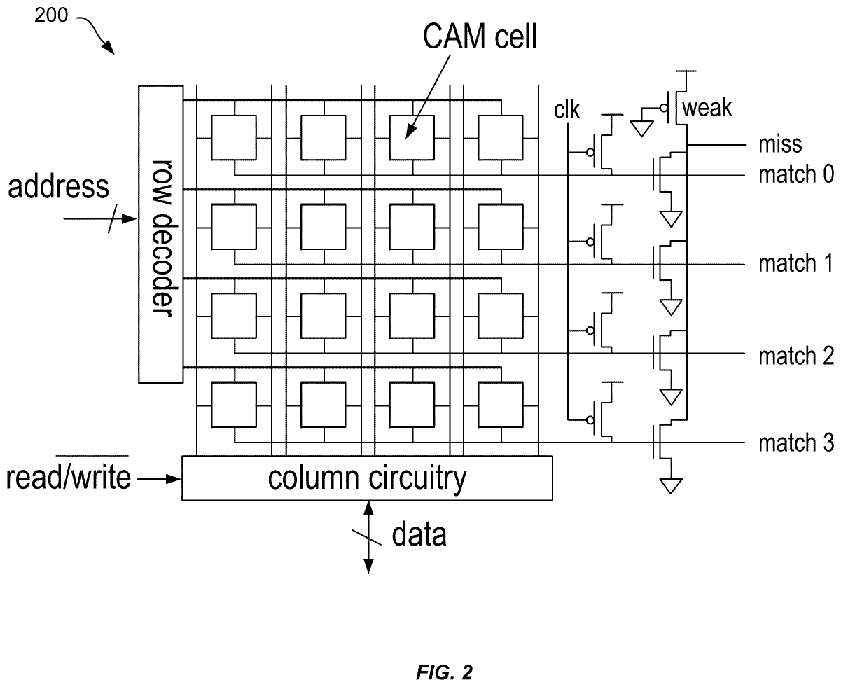

FIG. 2 is a top-level view of an example of CAM-based architecture. The CAM-based architecture can include a m×n array of CAM bit cells (BCs). Each of the BCs in the array can be identical to the CAM cell 100 from FIG. 1. The CAM-based architecture can include word lines, match lines, and bit lines (e.g., search lines). CAM cells can enable write and read operations through word lines and complimentary bit lines. Both write and read operations can be carried out by asserting the word lines. During read access, data of CAM cells can be sampled from the search lines following completion of a read by means of search line sensing circuitry.

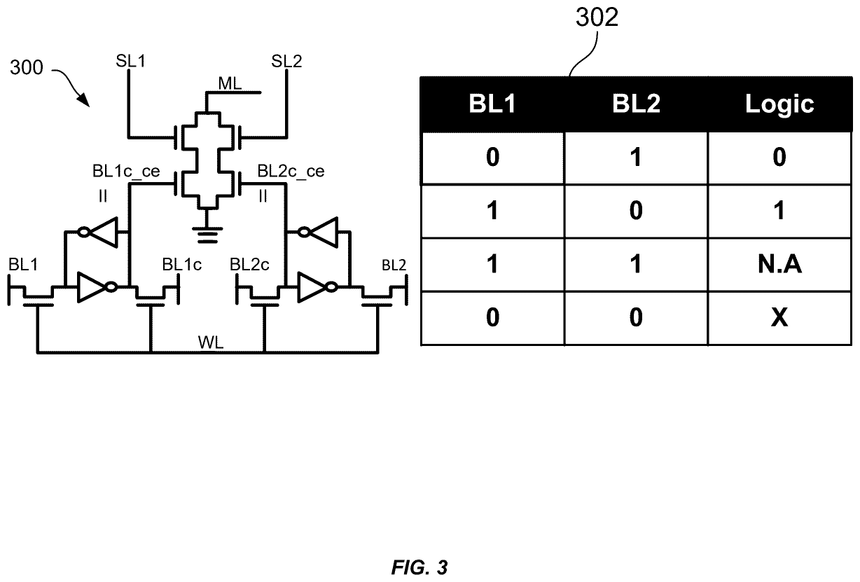

FIG. 3 is a schematic of a full CAM cell 300 with a table 302 of a complimentary bit line logic code associated with the full CAM cell 300 according to certain aspects of the present disclosure. The full CAM cell can include a word line (e.g., WL in FIG. 3), a match line (e.g., ML in FIG. 3), bit lines (e.g., BL1, BL2, BL1c, BL2c, BL1c_ce, and BL2c_ce in FIG. 3), and search lines (e.g., SL1 and SL2 of FIG. 3). The logic code described by Table 1 can be based on states associated with bit line BL1 and bitline BL2. For example, when the bit line BL1 is in an low signal off state or a ‘0’ state and the bit line BL2 is in a high signal on state or ‘1’ state, the logic code can be set to a ‘0’ state. The signal can be a voltage value. Additionally, when the bit line BL1 is in a high signal on state or a ‘1’ state and the bit line BL2 is in a low signal off state or ‘0’ state, the logic code can be set to a ‘1’ state. When both the bit line BL1 and bit line BL2 are in ‘1’ states, the logic code can be set to ‘N.A’. When both the bit line BL1 and bit line BL2 are in ‘0’ states, the logic code can be set to ‘X’. When sensed, the ‘X’ logic code value can indicate ‘do not care’, meaning that a bit with logic code X can be a match for either a ‘1’ or a ‘0’ of an input query. CAM architecture that uses three state logic code, such as the ‘1’, ‘0’, ‘X’ based logic code can be referred to as ternary CAM or TCAM architecture. In some examples, the full CAM cell can implement the logic code from table 302 as well as a mask. A mask can be an additional level or layer of code to handle more data than the logic code alone.

A main difference between CAM architecture and RAM architecture can be a compare operation or search operation present in CAM architecture. Compare operations can be applied by driving a query pattern onto search lines. A match can occur when stored data matches a query pattern, otherwise a mismatch can be asserted. Match and mismatch cases can depend on a voltage level of match lines. In some cases, such as approximate or similarity searches, a mismatch may not be asserted if the stored data does not match but is similar to the query pattern.

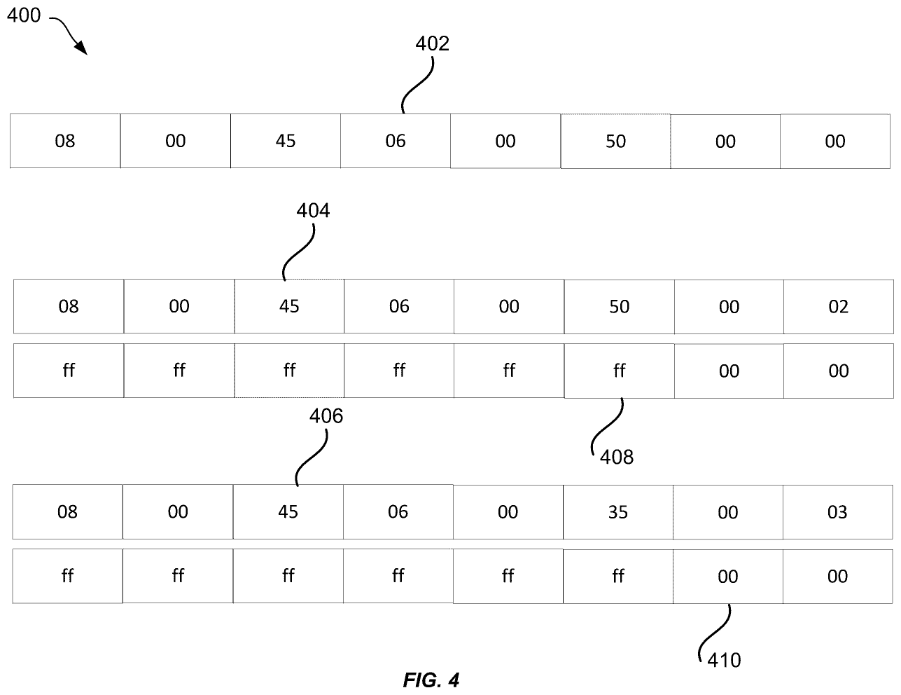

FIG. 4 is a schematic of a key and slot configuration for a compare operation of CAM architecture according to certain aspects of the present disclosure. The key and slot configuration can include a key 402, a first slot 404, and a second slot 406. The key 402, the first slot 404, and the second slot 406 can each be an array string with eight elements. Each slot can include an associated mask. For example, the first slot 404 can include an associated first mask 408. The second slot 406 can include an associated second mask 410. The key and slot configuration can be governed by an algorithm, such as the following:

```
for each slot do {
if (key == slot) {
  declare key matches slot;
} else {
  declare key does not match slot;
  }
}
### with mask
for each slot do {
    if (key & mask ) == (slot & mask)) {
    declare key matches slot;
} else {
  declare key does not match slot;
    }
}
```

Applying the above algorithm to the key and slot configuration above, for the first slot 404, the algorithm can return ‘key does not match slot’. Although many of the elements in the first slot 404 match elements in the key 402, a last element of the first slot 404 has a value of 02 in contrast to a value of 00 for a last element of the key 402. Similarly, applying the algorithm to the second slot 406 also can lead to ‘key does not match slot’ because two elements of the second slot 406 do not match up with corresponding elements of the key 402.

In conventional CAM architecture, a basic function to implement can take a form of F=ab′+a′b. Since a single SRAM cell can be used to handle the ‘a’ and ‘a′’ portions of such a function form, computer architecture designers can tend to use a single SRAM cell and add additional logic as shown in FIG. 1 above. When an additional mask bit is used to implement three states (such as ‘0’, ‘1’, and ‘X’ from FIG. 3) of a searchable bit, then second SRAM memory cell can be added, such as in the full CAM cell 300 of FIG. 3.

Certain aspects and examples of the present disclosure relate to a CAM search architecture that includes separating two data string types for a two SRAM based CAM memory cell in a n×m CAM based array. The CAM based array can include n rows and m columns and each CAM element can include two SRAM cells. The SRAM cells can be six transistor (6T) cells. A first SRAM cell in a CAM element can be associated with a first data type (e.g., ‘data’) and a second SRAM cell in the CAM element can be associated with a second data type (e.g., ‘data_b’).

Each column can be referred to as a set and each set can include n CAM elements. Additionally, the CAM based array can include two word line types for each row and two bit line types for each column. Write operations for an entire CAM array can be performed in two write steps. In a first write step, all ‘1’ states for the CAM based array can be written simultaneously. Only SRAM cells associated with the first data type may be written during the first write step. In a second write step, all ‘0’ states for the CAM based array can be written simultaneously. Only SRAM cells associated with the second data type may be written during the second write step.

Search operations for sets of the CAM array can be performed in parallel and can involve two search steps. In a first step, a set can be searched for any matches with a data query. In a second step, the set can be searched for any mismatches with a data query. The separate word lines for each row can be involved in the two search steps. The CAM search architecture can eliminate a glue logic found in traditional CAM cells. Glue logic can be logic that enables connections from one element or component to another element of component. A removal of glue logic from can reduce a complexity associated with CAM search architecture. The CAM search architecture can enable a reduction in an array size, CAM cell size, and an amount of spent search energy per bit compared to conventional CAM search architectures.

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

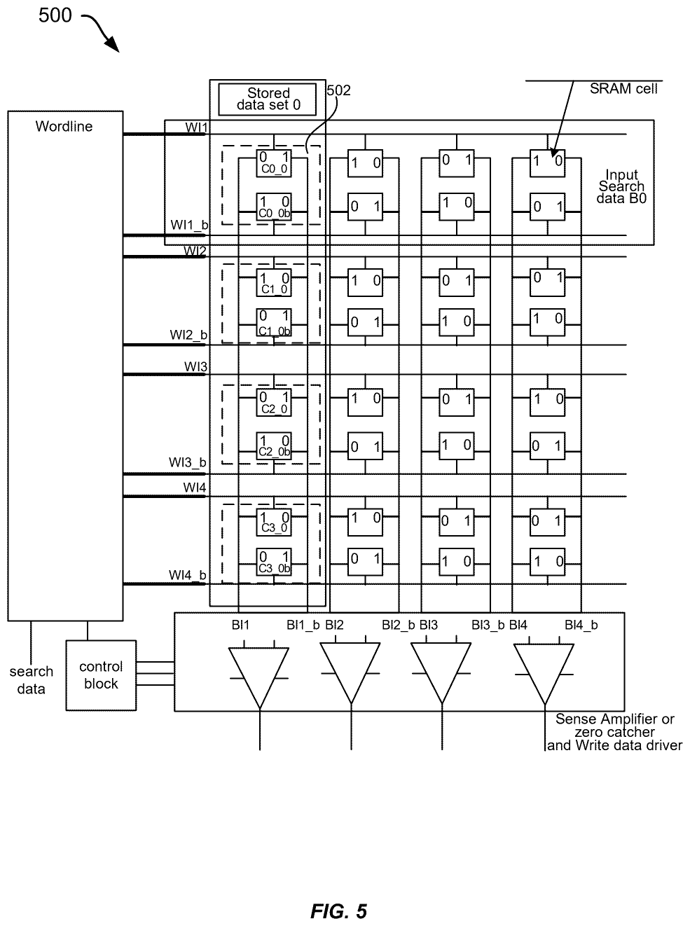

FIG. 5 is a schematic of a CAM-based system 500 for implementing a CAM search architecture according to certain aspects of the present disclosure. The CAM-based system 500 can include an m×n array having m rows and n columns of CAM cells, such as CAM cell 502. Both m and n can be any integer. For example, in FIG. 5, m=n=4. For simplicity, only one CAM cell is labeled in FIG. 5. The array shown in FIG. 5 includes 16 CAM cells, but the array can include any number of CAM cells, including a single CAM cell. For simplicity, only one CAM cell is labeled in FIG. 5. Each CAM cell can include multiple SRAM cells (e.g., two SRAM cells). Each SRAM cell can include six transistors and can be referred to as a 6T SRAM cell. For example, CAM cell 502 includes a first SRAM cell CO_0 and a second SRAM cell CO_0b.

The CAM-based system 500 can include two word lines for each row in the array and two bit lines for each column. For example, a first row of the array can include a first word line W11 and a second word line W11_b. Additionally, a first column of the array can include a first bit line B11 and a second bitline B12. The CAM-based system 500 can also include a sense amplifier, a control block, and a write-data driver.

The CAM-based system 500 can be designed to enable operations associated with rapidly searching input data for matches within the array. A first of three main operations associated with the CAM-based system 500 can be a write operation. A first step of a write operation can involve writing ‘0’ states to some SRAM cells within CAM cells of the array. The first step can involve enabling a word line and a write data driver to write ‘0’ states to CAM cells in each set of CAM cells. SRAM cells within the CAM cells that are written with the ‘0’ states can be categorized within a ‘data’ category. Additionally, the second step can involve writing on states or ‘1’ states for some SRAM cells within the CAM cells in the array. For the second step, the write-data driver can be enabled to write ‘1’ states instead of ‘0’ states. SRAM cells within the CAM cells that are written with the ‘1’ states can be categorized within a ‘data_b’ category. The write operation for the CAM-based system 500 can be a two-step operation as opposed to an n step operation performed by conventional CAM architectures.

A second main operation associated with the CAM-based system 500 can be a read operation. The read operation can be an uncommon or seldom executed operation associated with the CAM-based system 500. The read operation can involve determining a state of CAM cells or SRAM cells in the array. The read operation can involve columns of the array. A column can be referred to as a set of elements or CAM cells. A number (n) of rows in the array can determine a number of CAM cells in the set or a number of bits per set. Each CAM cell can be associated with a bit. A number of SRAM cells in the set can be twice the number of rows or 2n. A read operation of a particular set can involve n cycles to read data in the set. In some examples, to simplify the read operation, CAM cells in a single row of the CAM-based array can include SRAM cells with eight transistors (8T) instead of six transistors (6T). Two additional transistors in an 8T cell can be connected in a manner to read any set of stored data in a single cycle. But since read operations can be rare in CAM-based systems, the two additional transistors can be removed to avoid an unnecessary overhead.

A third main operation associated with the CAM-based system 500 can be a search operation. Details of the search operation can depend on characteristics of CAM cells or SRAM cells in the array. For example, the search operation can be different when the CAM cells or SRAM cells include mask data. Mask data can be an additional layer of data to associate with a bit in the array. The search operation will first be described below for the array with mask-less bits.

For each row of CAM cells in the array, one of two SRAM cells in the CAM cell can be associated with a first category of data (e.g., ‘data’). The other of the two SRAM cells can be associated with a second category of data (e.g., ‘data_b’). One word line for each row can be enabled to activate a search for SRAM cells associated with the first type of data and another word line in the row can be enabled to activate a search for SRAM cells associated with the second type of data.

During each search, a first bit line for a set (e.g., column of the array) can maintain a relatively high voltage signal and only discharge when a mismatch is sensed. The sense amplifier can translate a difference in potential between two bit lines of a set and output a signal that indicates a match or a mismatch. For example, for the first column, the sense amplifier can translate the potential difference between bit line Bl1 and bit line B11_b.

During the search operation, since a bit line can experience a discharge based on a number of identified mismatch bits, word lines can have a lowered voltage to avoid unintended writes of bits. The lowered voltage of the word lines can be less than write voltages associated with the SRAM cells. Additionally, to avoid a potential issue that can occur when a number of identified matched bits equals a number of identified mismatched bits, for each column, a capacitance of a first bit line can be reduced compared to a capacitance of a second bit line assigned to the same column. A voltage of the first bit line can be expected to remain high on a detection of a match. The capacitance reduction for the first bit line can ensure that if a mismatch is detected, a discharge or droop for the first bit line is increased.

The search operation will now be described for the array with bits that involve a mask. The search operation in such a case can be similar to the search operation for the array with mass-less bits with minor differences. For a bit that involves a mask, input data for the corresponding bit can be held to zero so the corresponding bit is not involved in a comparison.

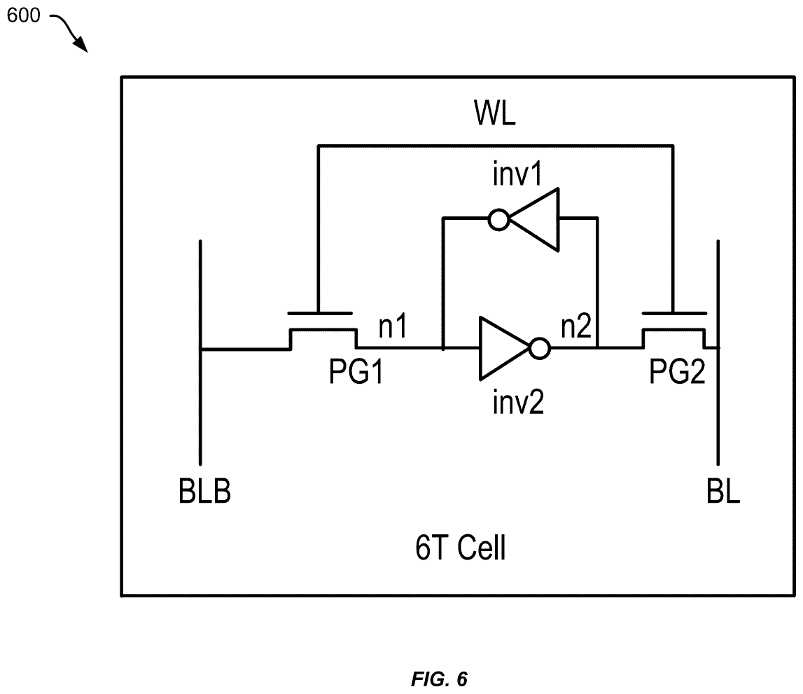

FIG. 6 is a schematic of an SRAM cell 600 for implementing a CAM search architecture according to certain aspects of the present disclosure. The SRAM cell 600 can be one of two SRAM cells included in a CAM cell of a CAM-based array, such as an array in CAM-based system 500 of FIG. 5. The SRAM cell 600 can be a six transistor (6T) SRAM element. The SRAM cell 600 can be associated and electrically connected with a single word line, such as the first word line W11 or the second word line W11_b of FIG. 5. Additionally, the SRAM cell 600 can be associated and electrically connected with a first bit line BL and a second bit line BLB.

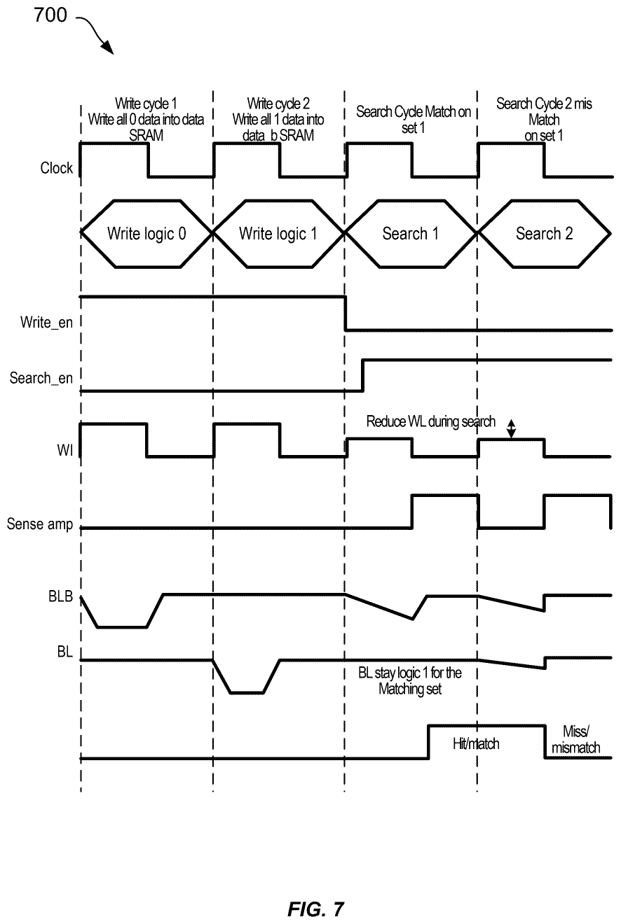

FIG. 7 is a diagram indicating signals of components in a CAM-based array system during various operations according to certain aspects of the present disclosure. The signals can involve voltage values. The various operations can involve two consecutive write cycles followed by two consecutive read cycles for various sets of CAM cells in an array of the CAM-based system. An example of the CAM-based system can be CAM-based system 500 of FIG. 5. Each CAM cell in an array in the CAM-based system can include multiple SRAM cells, such as two SRAM cells. A first write cycle can involve writing ‘0’ states to a first subset of SRAM cells in the CAM cells of the CAM-based array. The first subset of SRAM cells written with ‘0’ states can be categorized in a ‘data’ category. All of the SRAM cells in the first subset can be written simultaneously during the first write cycle. A second write cycle can involve writing ‘1’ states to a second subset of SRAM cells in the CAM cells of the CAM-based array. The second subset of SRAM cells written with ‘1’ states can be categorized in a ‘data_b’ category. All of the SRAM cells in the second subset can be written simultaneously during the second write cycle.

For each set, during both the first and second write cycles, word lines of the set can be activated with a signal during a first half of the write cycle and deactivated through removal of the signal during a second half of the write cycle. During the first write cycle, a first bit line BL for a set can be activated to logic ‘1’ through a signal. A second bit line BLB of the set can be deactivated to logic ‘0’ by removal of a voltage on the second bit line BLB during the first half of the first write cycle. The voltage on the second bit line BLB can be returned during the second half of the first write cycle. During the second write cycle, there can be a role reversal between the first bit line BL and the second bit line BLB. A state of ‘1’ can be maintained for the second bit line BLB throughout the second write cycle. The first bit line BL can be deactivated to logic ‘O’ by removal of a voltage on the first bit line BL during the first half of the second write cycle. The voltage on the first bit line BL can be returned during the second half of the second write cycle. A write data driver can be activated during both the first and second write cycles.

A first search cycle and a second search cycle can follow the first and second write cycles. During both cycles, the write data driver can be deactivated. For each set, during both the first and second search cycles, word lines of the set can be activated with a word search signal during a first half of the write cycle and deactivated through removal of the signal during a second half of the write cycle. The word search signal can be less than the signal on word lines during the write cycle. Such a reduction in a signal to the word lines can ensure that bits are not inadvertently written during either of the search cycles. The word search signal can be less than a write voltage for the SRAM cells.

During the first search cycle, the first bit line BL for can maintain logic ‘1’ with a high state signal. The second bit line BLB can begin the first search cycle with a high signal, but during a first half of the first search cycle, the second bit line BLB can discharge as matches are detected. Such a discharge of the second bit line BLB can cause the initially high signal on the second bit line BLB to drop linearly with time. During the second half of the first search cycle, the signal on the second bit line BLB can be high once again.

Both the first bit line BL and the second bit line BLB can begin the second search cycle with a high signal, but during a first half of the second search cycle, both the first bit line BL and the second bit line BLB can discharge as mismatches are detected. Such discharges can cause the initially high signals on both lines to drop linearly with time. A sense amplifier can be low during the first half of the first and second search cycles but become high during the second half of both search cycles to indicate detections (e.g., detections of matches during the first search cycle, detections of mismatches during the second search cycle, etc.). A search data driver can be in a low state during the first and second write cycles and in a high state during the first and second search cycles.

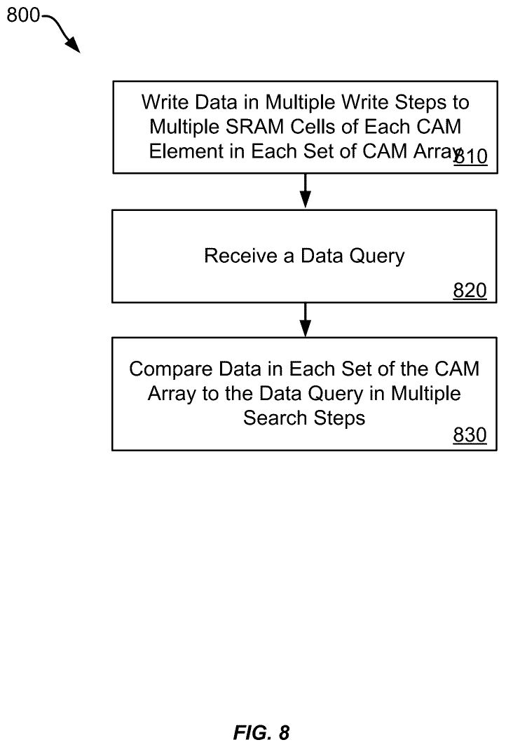

FIG. 8 is a flow chart of a process 800 for implementing operations associated with a CAM search architecture according to certain aspects of the present disclosure. Operations of processes may be performed by software, firmware, hardware, or a combination thereof. Other examples can involve more operations, fewer operations, different operations, or a different order of operations than shown in FIG. 8. The operations of the process 800 can begin at block 810.

At block 810, the process 800 involves writing data in multiple write steps to multiple SRAM cells of each CAM element in each set of a CAM array. The CAM array can be in a CAM-based system such as CAM-based system 500 of FIG. 5. The CAM array can be an n×m array with n rows and m columns. Each column can be referred to as a set and each set can include n CAM elements. Each of the CAM elements can include multiple SRAM cells, such as two SRAM cells. The SRAM cells can be 6T SRAM cells and each include six transistors. When the CAM elements include two SRAM cells, a first of the two SRAM cells can be associated with a ‘data’ dataset and the second of the two SRAM cells can be associated with a ‘data_b’ dataset.

Logic code associated with the CAM array can be a three state or ternary logic code. The logic code can be consistent with Table 1 described above. The CAM-based system can include, for each set of the CAM array, a first bit line BL1 and a second bit line BL2. The logic code can be based on states associated with the first bit line BL1 and the second bit line BL2. For example, when the first bit line BL1 is in a low signal off state or a ‘0’ state and the second bit line BL2 is in a high signal on state or ‘1’ state, the logic code can be set to a ‘0’ state. The signals can be voltage values. Additionally, when the first bit line BL1 is in a high signal on state or a ‘1’ state and the second bit line BL2 is in a low signal off state or ‘0’ state, the logic code can be set to a ‘1’ state. When both the first bit line BL1 and the second bit line BL2 are in ‘1’ states, the logic code can be set to ‘N.A’. When both the first bit line BL1 and the second bit line BL2 are in ‘0’ states, the logic code can be set to ‘X’. When sensed, the ‘X’ logic code value can indicate ‘do not care’, meaning that a bit with logic code X can be a match for either a ‘l’ or a ‘0’ of an input query. CAM architecture that uses three state logic code, such as the ‘1’, ‘0’, ‘X’ based logic code can be referred to as ternary CAM or TCAM architecture. In other examples, the logic code associated with the CAM array can be a two state or binary logic code and the CAM architecture can be referred to as binary CAM or BCAM.

The multiple write steps can be performed by a write data driver of the CAM-based system. In some examples, the multiple write steps can include two write steps. The write data driver can write data to multiple sets simultaneously during each of the two write steps. In a first write step, ‘0’ logic states can be written to at least a first portion of the CAM elements in the CAM array. In a second write step, ‘1’ logic states can be written to at least a second portion of the CAM elements in the CAM array. The first portion and the second portion may not overlap.

Each set of the CAM array can include a first word line WL1 and a second word line WL2. During at least a portion of each of the two write steps, a word line write signal (or voltage) can be applied to either or both the first word line WL1 and the second word line WL2. The word line write voltage can be greater than a threshold voltage associated with each SRAM element in the CAM elements. The threshold voltage can be a minimum voltage to write a particular data state to transistors in the SRAM elements.

At block 820, the process 800 involves receiving a data query. In some examples, the data query can be an input query pattern. The input query pattern can include n or m elements. In some examples a word line driver of the CAM-based system can receive the data query.

At block 830, the process 800 involves comparing data in each set of the CAM array to the data query in multiple search steps. In some examples, the multiple search steps can include two search steps. The two search steps can be performed by a search driver of the CAM-based system. The sets can be compared to the data query simultaneously. Comparing the data can involve searching for matches or mismatches between the sets and the data query. Matches can be detected during a first search step. Mismatches can be detected during a second search step.

The comparison between the data in each set and the data query can be based on a first bit line signal, a second bit line signal or a difference in signals applied to the first bit line BL1 and the second bit line BL2 for the set. Each of the bit line signals can fall or rise when a match or a mismatch is detected. The bit line signals can be voltages. In some examples, a capacitance of each first bit line BL1 can be less than a capacitance of each BL2. Such a capacitance reduction for the first bit line BL1 can ensure that if a mismatch is detected, a discharge or droop for the first bit line is increased. word line search signals to the first word line and the second word line during at least a portion of the two search steps, wherein the word line search signals are lower than the word line write signals, and wherein the search driver is further configured to compare, simultaneously, the data in the first and second word lines in each row to the data query.

In some examples, rows can be compared with the data query instead of the sets. For example, the comparison of the data to the data query can be based on word line search signals applied to the first and second word lines in each row. Word line search signals can be lower than word line write signals to avoid inadvertent writing of CAM elements during search operations.

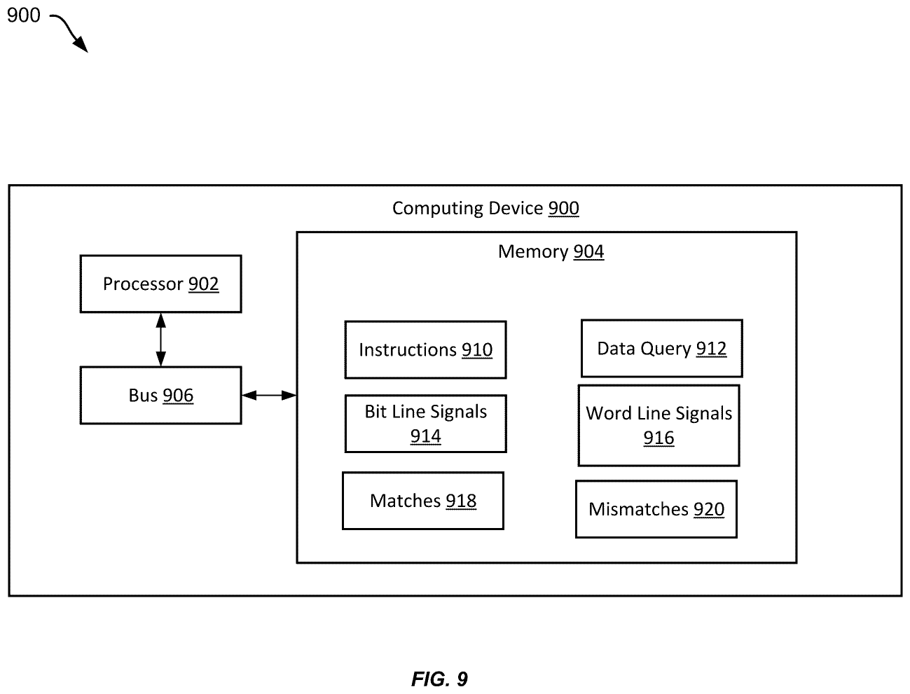

FIG. 9 is a block diagram of a computing device 900 that includes a CAM-based system according to certain aspects of the present disclosure. CAM-based system 500 from FIG. 5 can be an example of the CAM-based system. As shown, the computing device 900 includes a processor 902 communicatively coupled to memory 904. The processor 902 can include one processing device or multiple processing devices. Non-limiting examples of the processor 902 include a Field-Programmable Gate Array (FPGA), an application specific integrated circuit (ASIC), a microprocessor, or any combination of these. The processor 902 can execute instructions 910 stored in the memory 904 to perform operations, such as the operations of process 800 from FIG. 8. In some examples, the instructions 910 can include processor-specific instructions generated by a compiler or an interpreter from code written in any suitable computer-programming language, such as C, C++, C#, Python, or Java.

The memory 904 can include one memory device or multiple memory devices. The memory 904 can be non-volatile and may include any type of memory device that retains stored information when powered off. Non-limiting examples of the memory 904 include electrically erasable and programmable read-only memory (EEPROM), flash memory, or any other type of non-volatile memory. At least some of the memory 904 can include a non-transitory computer-readable medium from which the processor 902 can read instructions 910. The non-transitory computer-readable medium can include electronic, optical, magnetic, or other storage devices capable of providing the processor 902 with the instructions 910 or other program code. Non-limiting examples of the non-transitory computer-readable medium include magnetic disk(s), memory chip(s), RAM, an ASIC, or any other medium from which a computer processor can read instructions 910.

The memory 904 can further include a data query 912, bit line signals 914, word line signals 916, matches 918, and mismatches 920. The data query 912 can be received by components of the CAM-based system. The data query 912 can be compared to data in the CAM-based system. Comparing the data can involve detecting the matches 918 and mismatches 920. In some examples, the comparison can be based on values of the bit line signals 914 or the word line signals 916.

### Examples

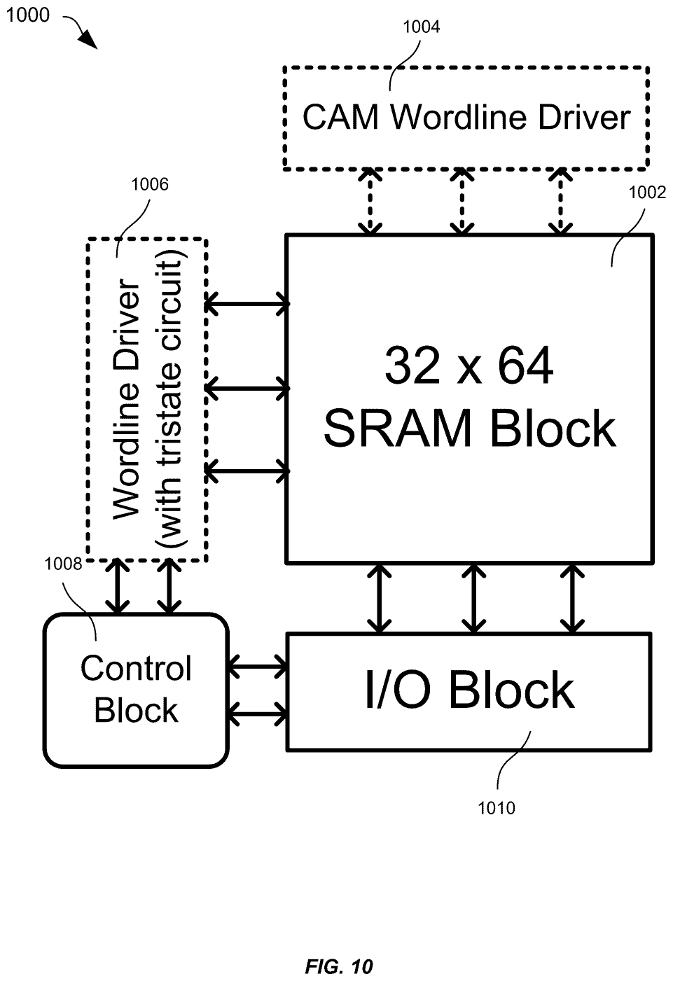

CAM array systems, such as CAM-based system 500 from FIG. 5 have been designed and analyzed. The CAM array systems were designed with various types of arrays. The various types of arrays included an SRAM array, a binary CAM (BCAM) array, a TCAM array, and a similarity index array. BCAM architecture can have binary logic that may not include an ‘X’ state, such as the ‘X’ state described in FIG. 3. The similarity index array can search for sets in the array that are similar to a data query and may not be an exact match to the query. FIG. 10 is a schematic of an analyzed CAM-based system 1000 for implementing a CAM search architecture according to certain aspects of the present disclosure.

The analyzed CAM-based system 1000 can include an m×n array 1002, such as a 32×64 SRAM array as shown in FIG. 10, a CAM wordline driver 1004, an additional wordline driver 1006, a control block 1008, and an I/O block 1010. Examples of the CAM-based system have been designed and analyzed using GlobalFoundry 22 nm FDSOI technology. The additional wordline can include a tristate or ternary state circuit. Other versions of the m×n array 1002 can include a BCAM array, a TCAM array, or a similarity index array. The CAM-based system 1000 can be configured to implement processes, such as process 900 described above.

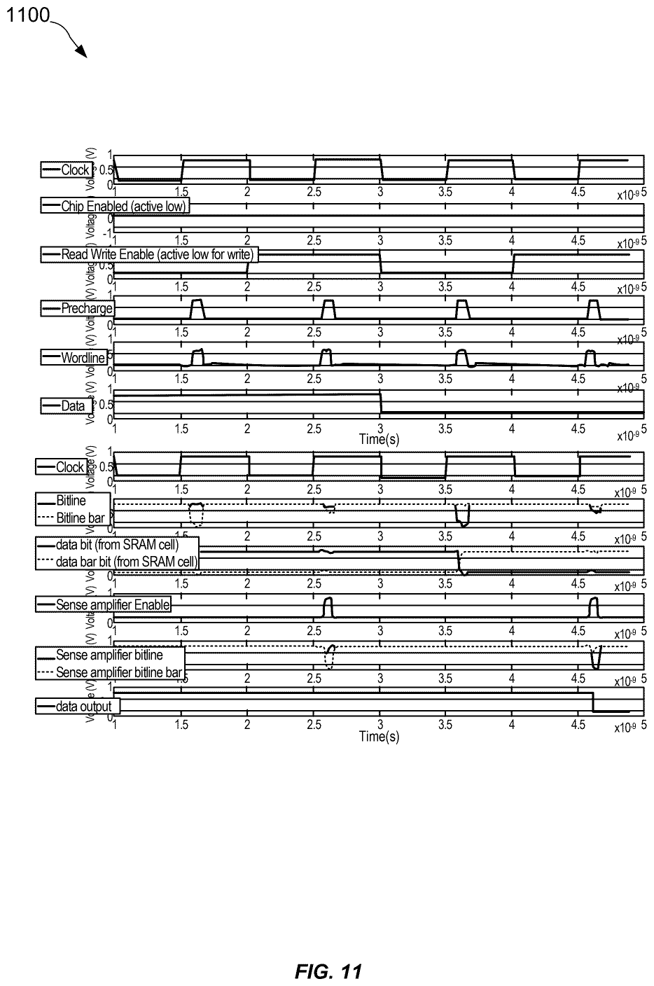

FIG. 11 is a graph 1100 with plots of timing waveforms associated with an SRAM array of a CAM-based system (e.g. CAM-based system 1000 from FIG. 10) for implementing a CAM search architecture according to certain aspects of the present disclosure. The plots of the timing waveforms can include time dependent voltage signals applied to various components of the CAM-based system during read and write operations.

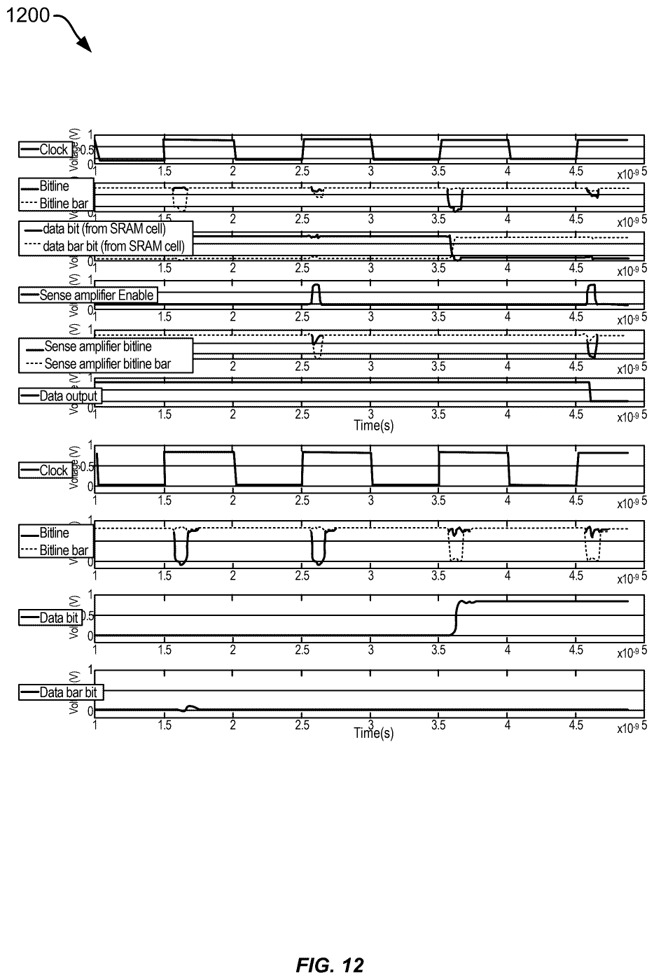

FIG. 12 is a graph 1200 with plots of timing waveforms associated with an CAM array of a CAM-based system (e.g., CAM-based system 1000 from FIG. 10) for implementing a CAM search architecture according to certain aspects of the present disclosure. The plots of the timing waveforms can include time dependent voltage signals applied to various components of the CAM-based system during write operations.

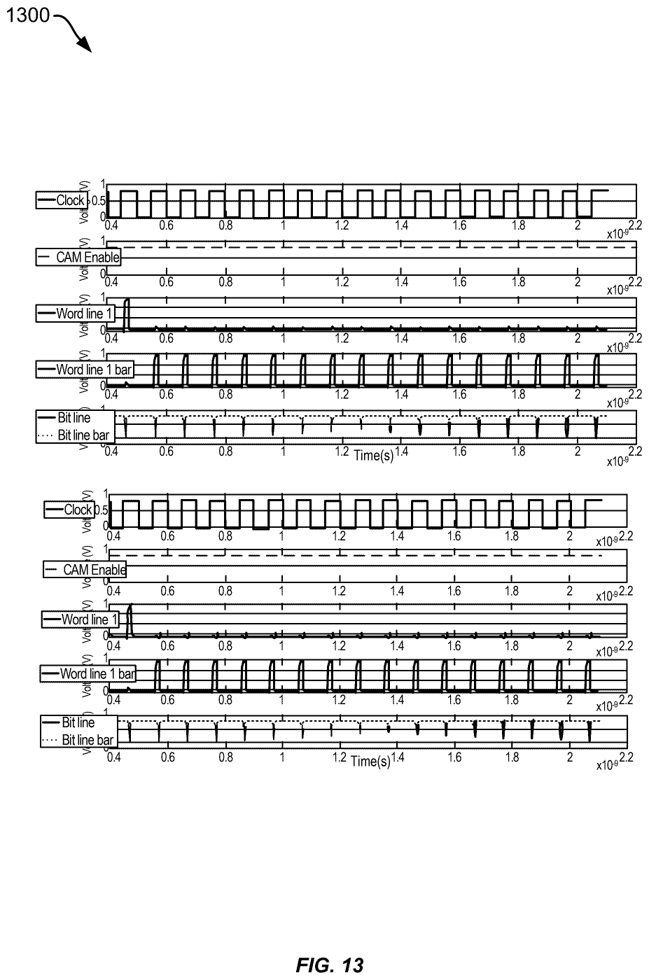

FIG. 13 is a graph 1300 with plots of timing waveforms associated with a similarity index array of a CAM-based system for implementing a CAM search architecture according to certain aspects of the present disclosure. The plots of the timing waveforms can include time dependent voltage signals applied to various components of the CAM-based system during write operations.

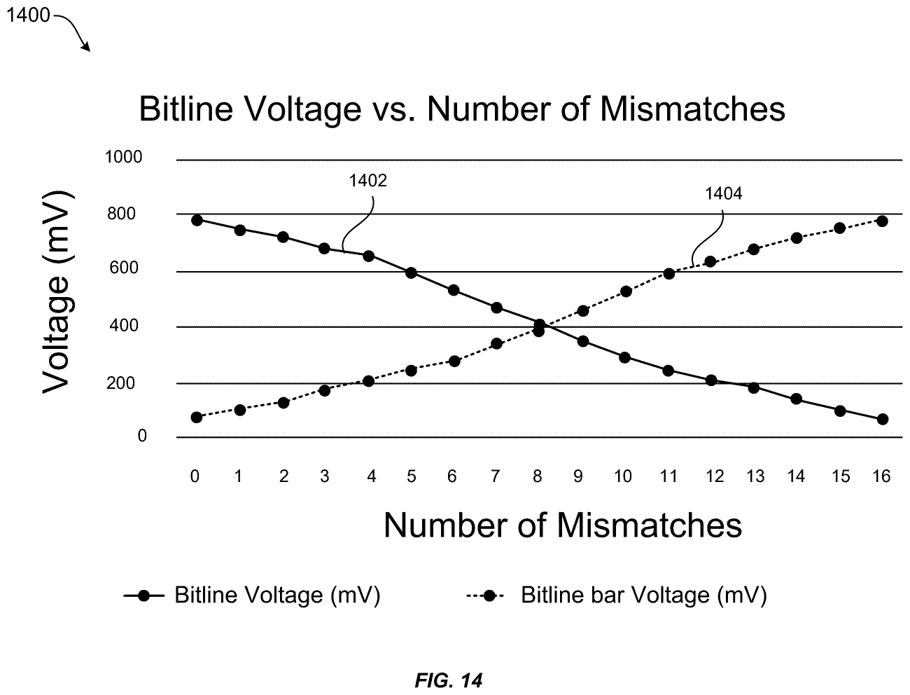

FIG. 14 is a graph 1400 with plots of voltage dependences on a number of identified mismatches for a first bit line and a second bit line in a CAM array of a CAM-based system according to certain aspects of the present disclosure. CAM-based system 500 is one example of the CAM-based system. The first bit line can be referred to as ‘bit line’ and the second bit line can be referred to as ‘bit line_b’ or ‘bit line bar’. Voltages of either the first bit line or the second bit line can be used to identify mismatches with an input data query for the CAM-based system during a search operation. As mismatches are identified, the voltage associated with the first bit line can fall and voltages associated with the second bit line can rise. A difference between the two bit lines can also be monitored to identify mismatches.

For example, a voltage difference between the first bit line and the second bit line can fall from a positive value to about zero as mismatches are identified up to eight mismatches. As additional mismatches beyond eight mismatches are identified, the voltage difference can become negative with an increasing negative magnitude. The voltage difference can also be defined as the voltage difference between the second bit line and the first bit line (e.g., the difference can be negative before eight mismatches are identified. Although the difference between the two voltages falls to about zero for eight mismatches, in other examples, the zero-voltage difference value can occur for a different number of mismatches.

Additionally, or alternatively, matches can be detected between elements in the CAM array and a data query during a first step. At least one entry can be identified that closely matches a multiple bit in an element. Each bit of search data in the data query can be compared to a corresponding bit in stored data. Depending on a number of detected matches, a value of a voltage on a bit line (e.g., the first bit line, the second bit line, etc.) can be set.

TABLE 1
Comparison of CAM-based System with other conventional CAM-based architectures.

| Property | CAM-Based Sytem | | Conventional 1 | | Conventional 2 | | Conventional 3 | | Conventional 4 | |
|---|---|---|---|---|---|---|---|---|---|---|
| Technology | 22 | nm | 28 | nm | 32 | nm | 28 | nm | 65 | nm |
| Transistor/ | 12 | T | 12 | T | 16 | T | 16 | T | 16 | T |

| | | | | | |
|---|---|---|---|---|---|
| Cell | | | | | |
| Area/cell | 0.246 | 0.304 | NA | 0.625 | 1.69 |
| (μm)² | | | | | |
| Energy/search/ | 0.441 | 0.74 | 0.58 | NA | 1.98 |
| bit (fJ) | | | | | |
| Frequency | 1000 | 370 | 1000 | 400 | 250 |
| (MHz) | | | | | |
| Array size | 16 × 64 | 32 × 64 | 128 × 128 | (4k × | (2k × |
| | | | | 80) × | 72) × |
| | | | | 64 × 4 | 32 × 4 |
| Modes | BCAM/TCAM/SRAM/ | BCAM/TCAM/ | TCAM | TCAM | TCAM |
| | Similarity Index | SRAM | | | |

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, it should be understood that the present disclosure has been presented for purposes of example rather than limitation, and does not preclude inclusion of such modifications, variations, and/or additions to the present subject matter as would be readily apparent to one of ordinary skill in the art. Indeed, the methods and systems described herein may be embodied in a variety of other forms; furthermore, various omissions, substitutions, and changes in the form of the methods and systems described herein may be made without departing from the spirit of the present disclosure. The accompanying claims and their equivalents are intended to cover such forms or modifications as would fall within the scope and spirit of the present disclosure.

Conditional language used herein, such as, among others, “can,” “could,” “might,” “may,” “e.g.,” and the like, unless specifically stated otherwise, or otherwise understood within the context as used, is generally intended to convey that certain examples include, while other examples do not include, certain features, elements, and/or steps. Thus, such conditional language is not generally intended to imply that features, elements and/or steps are in any way required for one or more examples or that one or more examples necessarily include logic for deciding, with or without author input or prompting, whether these features, elements and/or steps are included or are to be performed in any particular example.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain examples require at least one of X, at least one of Y, or at least one of Z to each be present.

Use herein of the word “or” is intended to cover inclusive and exclusive OR conditions. In other words, A or B or C includes any or all of the following alternative combinations as appropriate for a particular usage: A alone; B alone; C alone; A and B only; A and C only; B and C only; and all three of A and B and C.

The use of the terms “a” and “an” and “the” and similar referents in the context of describing the disclosed examples (especially in the context of the following claims) are to be construed to cover both the singular and the plural, unless otherwise indicated herein or clearly contradicted by context. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. The use of “adapted to” or “configured to” herein is meant as open and inclusive language that does not foreclose devices adapted to or configured to perform additional tasks or steps. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. Additionally, the use of “based on” is meant to be open and inclusive, in that a process, step, calculation, or other action “based on” one or more recited conditions or values may, in practice, be based on additional conditions or values beyond those recited. Similarly, the use of “based at least in part on” is meant to be open and inclusive, in that a process, step, calculation, or other action “based at least in part on” one or more recited conditions or values may, in practice, be based on additional conditions or values beyond those recited. Headings, lists, and numbering included herein are for ease of explanation only and are not meant to be limiting.

The various features and processes described above may be used independently of one another or may be combined in various ways. All possible combinations and sub-combinations are intended to fall within the scope of the present disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed examples. Similarly, the example systems and components described herein may be configured differently than described. For example, elements may be added to, removed from, or rearranged compared to the disclosed examples.

All references, including publications, patent applications, and patents, cited herein are hereby incorporated by reference to the same extent as if each reference were individually and specifically indicated to be incorporated by reference and were set forth in its entirety herein.

What is claimed is:

1. A system comprising:
a content addressable memory (CAM) array comprising:
n rows and m columns of CAM elements, wherein each column of the m columns comprises a set with n CAM elements;
a first word line and a second word line in each row of the n rows; and
a first bit line and a second bit line in each column of the m columns; and
a write data driver configured to simultaneously write data to multiple static random-access memory (SRAM) cells of a CAM element in each set in the CAM array in multiple write steps.

2. The system of claim 1, wherein each CAM element of the CAM elements comprises:
a first static random-access memory (SRAM) cell configured to be written during a first write step; and
a second SRAM cell configured to be written during a second write step.

3. The system of claim 1, wherein each SRAM cell of the multiple SRAM cells comprises six transistor (6T) SRAM cells.

4. The system of claim 1, wherein the write data driver is further configured to write all ‘0’ states for the CAM array during a first write step.

5. The system of claim 1, wherein the write data driver is further configured to write all ‘1’ states for the CAM array during a second write step.

6. The system of claim 1, wherein the write data driver is further configured to, for each set, apply a high signal to the first bit line in the set and a low signal to the second bit line in the set during a first write step.

7. The system of claim 1, wherein the CAM array is configured to receive a data query, the CAM array further comprising a search driver configured to simultaneously compare data in each set of the CAM array to the data query in multiple search steps.

8. The system of claim 7, wherein the search driver is further configured to simultaneously compare the data in each set to the data query based on a difference in signals applied to the first bit line and the second bit line for the set.

9. The system of claim 7, wherein the search driver is further configured to detect matches between the data in each set and the data query during a first search step.

10. The system of claim 9, wherein the CAM array is configured to set a value of a bit line voltage based on a number of detected matches.

11. The system of claim 7, wherein the search driver is further configured to detect mismatches between the data in each set and the data query during a second search step.

12. The system of claim 7, wherein the CAM array is configured to apply word line write signals to the first word line and the second word line during a first write step and a second write step.

13. The system of claim 12, wherein the CAM array is configured to apply word line search signals to the first word line and the second word line during at least a portion of two search steps, wherein the word line search signals are lower than the word line write signals, and wherein the search driver is further configured to compare, simultaneously, the data based to the data query based on word line search signals in the first and second word lines in each row.

14. A method comprising:
writing, simultaneously, data in multiple write steps to multiple static random-access memory (SRAM) cells of each content addressable memory (CAM) element in each set of a CAM array, wherein the CAM array comprises:
n rows and m columns of CAM elements, wherein each column of the m columns comprises a set with n CAM elements;
a first word line and a second word line in each row of the n rows; and
a first bit line and a second bit line in each column of the m columns.

15. The method of claim 14, wherein writing the data in multiple write steps comprises, writing all ‘0’ states for the CAM array during a first write step.

16. The method of claim 14, wherein writing the data in multiple write steps comprises, writing all ‘1’ states for the CAM array during a second write step.

17. The method of claim 14, further comprising:
receiving a data query; and
comparing, simultaneously, data in each set of the CAM array to the data query in multiple search steps.

18. The method of claim 17, wherein comparing the data in each set comprises detecting matches between the data in each set and the data query during a first search step.

19. The method of claim 18, further comprising setting a value of a bit line voltage based on a number of detected matches.

20. The method of claim 17, wherein comparing the data in each set comprises detecting mismatches between the data in each set and the data query during a second search step.
